(19) United States
(12) Patent Application Publication
(10) Pub. No.: US 2011/0025943 A1
(43) Pub. Date: Feb. 3, 2011

(54) DISPLAY DEVICE

(75) Inventor: Shiyoshi Cho, Osaka-shi (JP)

Correspondence Address: SHARP KABUSHIKI KAISHA;C/O KEATING & BENNETT, LLP, 1800 Alexander Bell Drive, SUITE 200, Reston, VA, 20191, US

(73) Assignee: SHARP KABUSHIKI KAISHA, Osaka-shi, Osaka (JP)

(21) Appl. No.: 12/935,928

(22) PCT Filed: Feb. 26, 2009
(86) PCT No.: PCT/JP2009/053514

§ 371 Date: Oct. 1, 2010

(30) Foreign Application Priority Data
May 27, 2008 (JP) 2008-138011

(51) Int. Cl. G02F 1/1333; H05K 5/02

(52) U.S. Cl. 349/58; 312/326

(57) ABSTRACT

A display device 1 including a cabinet 4 that includes a front case 41 accommodating a liquid crystal panel 2 and a back case 42 accommodating a backlight unit 3, a hinge 5 that is attached on one lateral side of the cabinet 4 and is arranged to connect the front case 41 and the back case 42, an opening 7 that is formed on the other lateral side of the cabinet 4, and a movable supporting rod 6 that is attached on the lateral side of the cabinet 4 where the opening 7 is provided and is arranged to support the front case 41 when the front case 41 turns to open in a horizontal direction.

### TECHNICAL FIELD

The present invention relates to a display device, and specifically relates to a display device favorably used for an oversize liquid crystal display device.

### BACKGROUND ART

Conventionally, a liquid crystal display device equipped with a backlight, which is constituted of a liquid crystal panel and a backlight unit, is in widespread use. This type of liquid crystal display device has a configuration such that a cabinet accommodates components including the liquid crystal panel and the backlight unit. In performing maintenance of the device such as change of the backlight, it is necessary to open the cabinet for access to the inside of the device. In recent years, a screen of a display device has been increasing in size as seen in a big-screen television. For example, in the case of an oversize television with a 40-inch or more diagonal screen, it is not easy to detach the liquid crystal panel and get access to the backlight unit compared with the case of an undersize television. This is because the oversize liquid crystal display device is heavy and large, so that it is extremely difficult for one person to move the device by lifting it up.

In order to solve such a problem, a liquid crystal display device including a cabinet that is constituted of two members of a front case that accommodates a liquid crystal panel, and a back case that accommodates a backlight unit is disclosed and publicly known (see Japanese Patent Application Laid-Open Publications Nos. Hei 07-28056 and 2007-232937). This type of liquid crystal display device is provided with a hinge on either one lateral side of the cabinet, and the front case accommodating the liquid crystal panel opens on the hinge in a horizontal direction while the liquid crystal panel maintains its normal installation position such that the liquid crystal panel surface is vertical, which allows access to the backlight unit of the back case.

### SUMMARY OF INVENTION

### Technical Problem

Usually, maintenance of an oversize display device is performed at its installation site by a worker such as a service engineer because the oversize display device is not easily transported or moved. In the case of the conventional liquid crystal display device described above, since the liquid crystal panel side (the front case) is openable and closable, opening the front case while the display device rests at the installation site allows access to the inside of the display device.

However, concerns rise that structural members of the oversize display device are deformed by the weight of the display device when opening the front case. To be specific, a hinge structure that connects the front case and the back case of the cabinet could be deformed or broken by a large force exerted thereon if there is no member for supporting the panel. Considering these concerns, in a conventional display device 100 shown in FIG. 7, an operation of changing a backlight 106 and other components installed in a back case 105 is performed as follows: a leg member 103 equipped with a wheel 102 is temporarily secured by screws 104 to a front case 101 at a lower corner on an opening side thereof, and then the front case 101 is opened while being supported by the leg member 103 to perform the changing operation.

However, a repairperson needs to always carry the leg member 103 since the use of the leg member 103 is indispensable in getting access to the inside of the display device 100, which results in inconvenience for the repairperson. In addition, operations of temporarily securing the leg member 103 to the front case 101 by the screws 104 and detaching it therefrom are indispensable, which are complicated operations and thus results in difficult maintenance.

An object of the invention is to overcome the problems described above and to provide an easy maintenance display device such that, even if being oversize, maintenance of the inside of the device by opening its cabinet can be easily performed.

### Solution to Problem

In order to overcome the problems described above, preferred embodiments of the present invention provide a display device including a cabinet including a first case that accommodates components, a second case that accommodates components, a hinge that is attached on sides of the first case and the second case and is arranged to connect the first case and the second case, an opening that is openable and closable on a side of the cabinet, the side being opposite to the sides of the first and second cases of the cabinet on which the hinge is attached, and a supporting unit that is attached on the side of the cabinet where the opening is provided, and is arranged to, when one of the first and second cases is opened, support the opened case.

### ADVANTAGEOUS EFFECTS OF INVENTION

In the display device according to the preferred embodiments of the present invention, the supporting unit that is arranged to, when the first case or the second case is opened, support the opened case, can support the opened case when the case is opened, which allows maintenance of the inside of the device by opening the case to be performed without using a leg member that is used in the case of a conventional display device. Since the use of the leg member is not required, a repairperson does not need to carry a leg member, which eliminates the inconvenience of carrying the leg member.

In addition, since the display device according to the preferred embodiments of the present invention includes the supporting member attached on the opening side of the cabinet and arranged to support the case when the case is opened, there is no need to perform operations of temporarily securing a leg member by screws and detaching it therefrom, which are required in a conventional display device, so that the case is easily opened, allowing an easy maintenance display device.

Thus, according to the preferred embodiments of the present invention, the easy maintenance display device such that, even if being oversize, maintenance of the inside of the device by opening its cabinet can be easily performed can be provided.

### BRIEF DESCRIPTION OF DRAWINGS

FIG. 1 is a schematic view for explaining a liquid crystal display device as one example of a display device according to a preferred embodiment of the present invention, where a front case of the device is opened.

FIGS. 2A and 2B are end views of the display device shown in FIG. 1, and shown is one lateral side of the display device where an opening is provided. The opening is closed in FIG. 2A, and the opening is opened in FIG. 2B.

FIG. 3A is an enlarged view of a lateral side of a back case of the display device shown in FIG. 1, and FIG. 3B is a cross-sectional view of the display device shown in FIG. 3A.

FIG. 4 is a cross-sectional view of a backlight chassis inside the back case along the line A-A of FIG. 3A.

FIGS. 5A and 5B are end views of the display device according to another preferred embodiment of the present invention, and shown is the lateral side of the display device where the opening is provided, where a plurality of supporting rods are provided. The opening is closed in FIG. 5A, and the opening is opened in FIG. 5B.

FIG. 6 is an exploded perspective view showing one example of the internal structure of the liquid crystal display device.

FIG. 7 is a view for explaining a conventional display device.

### DESCRIPTION OF EMBODIMENTS

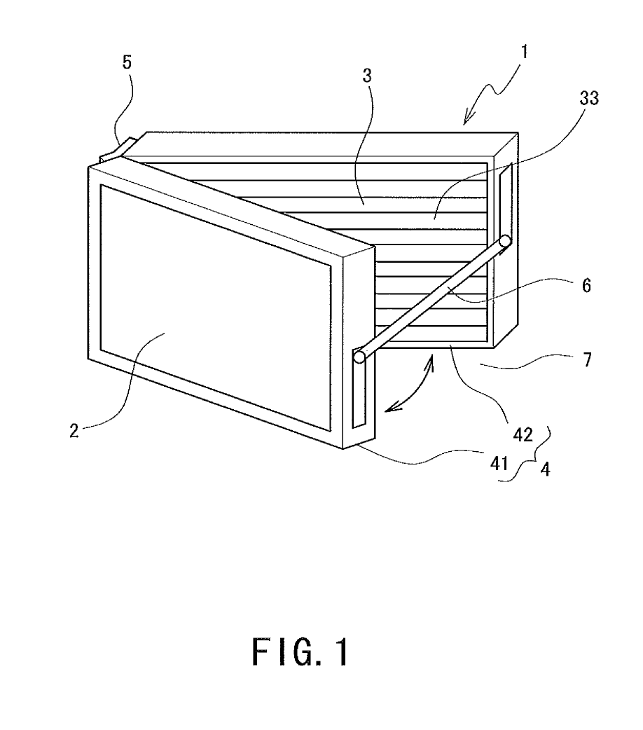

A detailed description of a display device according to preferred embodiments of the present invention will now be provided with reference to the accompanying drawings. FIG. 1 is a schematic view for explaining a liquid crystal display device as one example of the display device according to one of the preferred embodiments of the present invention, where a front case of the display device is opened. The liquid crystal display device shown in FIG. 1 as one example of the display device is equipped with a backlight. In FIG. 1, a liquid crystal display device (hereinafter, sometimes referred to simply as a display device) 1 includes a cabinet 4 that accommodates a liquid crystal panel 2 and a backlight unit 3. The cabinet 4 is constituted of a front case 41 that defines a first case, and a back case 42 that defines a second case. The front case 41 accommodates the liquid crystal panel 2 that defines a display panel of the display device 1. The back case 42 accommodates the backlight unit 3 that defines a light source for the liquid crystal panel 2. A bezel is preferably used for the front case 41. A backlight chassis is preferably used for the back case 42. The front case 41 and the back case 42 are each made preferably from a metal plate subjected to press working so as to have a square box shape with an opening on one surface thereof.

In the display device 1, the cabinet 4 is provided with a hinge 5, an opening 7 and a movable supporting rod (supporting unit) 6 as shown in FIG. 1. The hinge 5 is attached on the right or left side of the cabinet 4 (in FIG. 1, attached on the left side) and arranged to connect the two cases (the front case 41 and the back case 42) at their lateral sides. The opening 7 is openable and closable and formed on the lateral side of the cabinet 4 that is opposite to the side on which the hinge 5 is attached (in FIG. 1, formed on the right side). The supporting rod 6 arranged to support the opened front case 41 when the front case 41 is opened in a horizontal direction is attached on the side of the cabinet 4 where the opening 7 is formed. One end of the supporting rod 6 is connected to the front case 41 and the other end is connected to the back case 42. The hinge 5 has a hinge structure that connects the cases 41 and 42 in such a manner that the cases 41 and 42 turn around their lateral sides, and various kinds of hardware are preferably used for the hinge 5.

In the display device 1, the cabinet 4 is configured such that the front case 41 turns to open in the horizontal direction on the hinge 5 attached on the right or left side of the cabinet 4. Turning to open in the horizontal direction, the cabinet 4 is easy to open and close even if the display device 1 is oversize and heavy. In the display device 1 shown in FIG. 1, the cabinet 4 has a configuration such that the front case 41 opens while the back case 42 is fixed to a wall or a stand at an installation site of the display device 1 (not shown). Hence, when the front case 41 is opened and detached from the back case 42, the backlight unit 3 accommodated in the back case 42 is exposed, so that maintenance of the display device 1 such as change of cold cathode fluorescent tubes 33 can be performed. Since the front case 41 is supported by the back case 42 by means of the supporting rod 6 when opened, loads imposed on structural members of the display device 1 such as the hinge 5 are dispersed to prevent the structural members from being deformed or broken.

It is to be noted that in the preferred embodiments of the present invention, the front side of the display device 1 defines a side where the liquid crystal panel 2 that is arranged to display an image in a visible manner is disposed, and the back side of the display device 1 defines a back-surface side of the display device 1, which is a side where the backlight unit 3 is disposed in FIG. 1. In addition, the lateral sides of the display device 1 define the right side and the left side of the display device 1 when the display device 1 is seen from the front side.

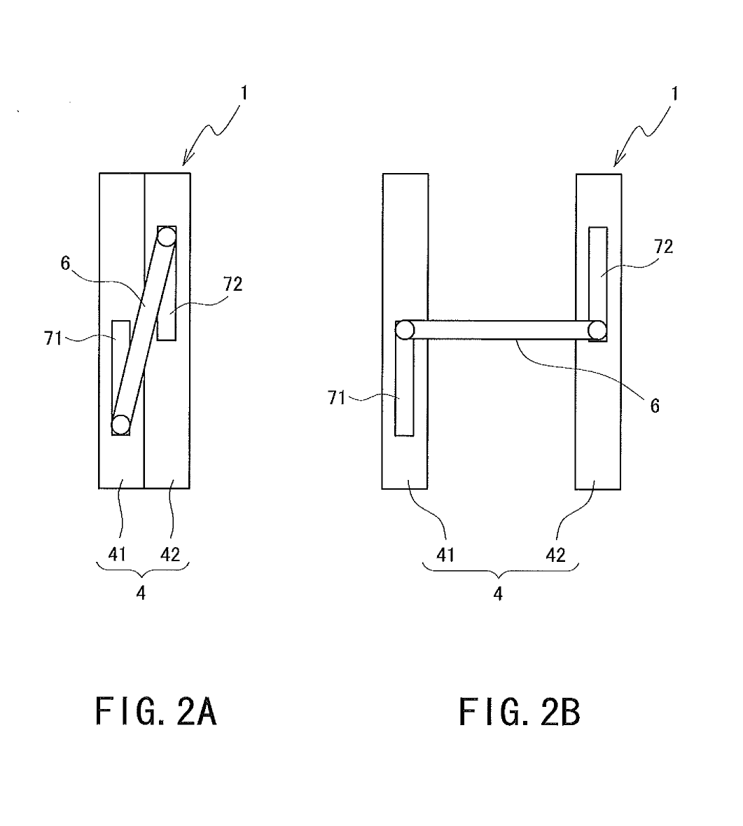

FIGS. 2A and 2B are end views of the display device shown in FIG. 1, and shown is one lateral side of the display device where the opening is provided. The opening is closed in FIG. 2A, and the opening is opened in FIG. 2B. As shown in FIGS. 2A and 2B, on the lateral side of the cabinet 4, guide slits 71 and 72 are provided in a vertical direction to the front case 41 and the back case 42, respectively. As shown in FIG. 2A, while the front case 41 of the display device 1 is closed and the opening 7 is accordingly closed, the supporting rod 6 is held by the cabinet 4 in a manner fixed to the lateral side of the cabinet 4 so as not to protrude forward or backward of the display device 1. In this case, the supporting rod 6 is housed such that one end of the supporting rod 6 fits into the lower end of the guide slit 71 and the other end fits into the upper end of the guide slit 72. Since the supporting rod 6 is held in the fixed manner by the cabinet 4 while the opening 7 is closed, the supporting rod 6 is unobtrusive while the cabinet 4 is closed.

The ends of the supporting rod 6 are attached to the front case 41 and the back case 42 so as to be vertically movable along the guide slits 71 and 72. When opening the front case 41 of the display device 1, the end of the supporting rod 6 that is attached to the front case 41 moves upward along the guide slit 71, and the end of the supporting rod 6 that is attached to the back case 42 moves downward along the guide slit 72 as shown in FIG. 2B. The supporting rod 6 moves in conjunction with the opening and closing operation of the opening 7 that is made by opening and closing the front case 41 such that the ends of the supporting rod 6 move vertically along the guide slits 71 and 72. Thus, the need for extra operations such as pulling out and putting back the supporting rod 6 when opening and closing the front case 41 is eliminated.

In FIG. 2B, the display device 1 is shown having the front case 41 opened to a maximum extent, where being moved to an almost horizontal position, the supporting rod 6 connects and supports the front case 41 and the back case 42. The opening angle of the opening 7 that is formed by turning to open the front case 41 on the hinge 5 in the horizontal direction and opening the opening 7 (i.e., the opening angle defines an angle which the front case 41 forms with the back case 42) can be adjusted as appropriate by changing the length of the supporting rod 6 or the lengths of the guide slits 71 and 72. In order to further facilitate the maintenance, the opening angle is preferably 45 degrees or more. In addition, the space of the opening 7 between the front case 41 and the back case 42 is preferably as long as the length of the shorter side of the cabinet 4.

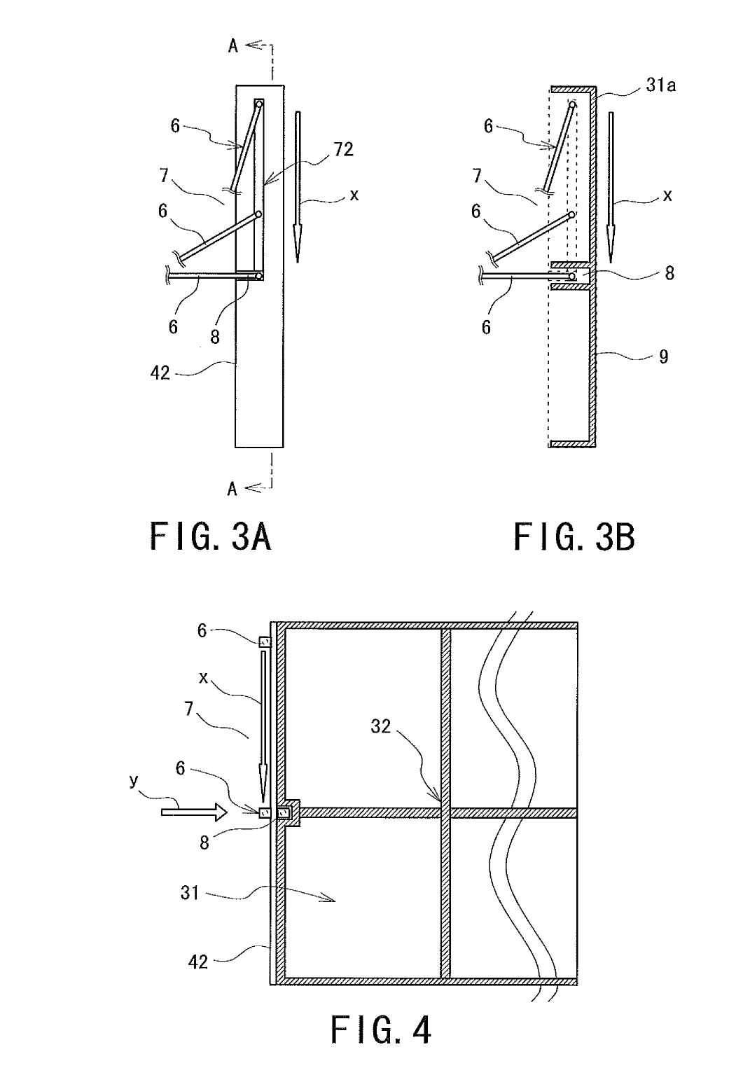

The display device according to another preferred embodiment of the present invention includes a fixing unit arranged to hold and fix the supporting rod (supporting unit) 6 to a predetermined position in order to fix the opening 7 in a predetermined open state at a given angle. FIG. 3A is an enlarged view of the lateral side of the back case of the display device shown in FIG. 1, and FIG. 3B is a cross-sectional view of the display device shown in FIG. 3A. FIG. 4 is a cross-sectional view of a backlight chassis inside the back case along the line A-A of FIG. 3A, which shows a portion of the backlight chassis that is close to the opening side. In FIG. 1, the display device is shown such that the supporting rod 6 is fixed while the opening is opened to a maximum extent. To be specific, the fixing unit is a recessed portion 8 shown in FIGS. 3A, 3B and 4, and the recessed portion 8 is arranged to hold and fix the supporting rod 6 in an almost horizontal state and provided to the guide slit 72 on the opening side of the back case 42.

As shown in FIGS. 3A, 3B and 4, a backlight chassis 31 of the backlight unit 3 is used for the back case 42. The backlight chassis 31 includes ribs 32 for stiffness enhancement. The recessed portion 8 is formed in a sideboard 31a of the backlight chassis 31 and has the shape of an almost horizontal channel that is recessed from the edge of the opening side. The recessed portion 8 is high enough to house the supporting rod 6, and is almost as long as the thickness of the backlight chassis 31.

In turning to open the front case 41 in the horizontal direction, the end of the supporting rod 6 moves downward along the guide slit 72 (in a direction indicated by the arrow X) as shown in FIGS. 3A and 3B. Reaching the lower end of the guide slit 72, the end of the supporting rod 6 is pushed into the inside of the recessed portion 8 (in a direction indicated by the arrow Y). The end of the supporting rod 6 fits into the inside of the recessed portion 8 as shown in FIG. 4 so that the supporting rod 6 is in an almost horizontal position, and thus the end of the supporting rod 6 is fixed to that position. Providing the recessed portion 8 allows the supporting rod 6 to support the front case 41 in a more stable manner.

It is also preferable that the display device 1 includes a recessed portion (not shown) at the upper end of the guide slit 71 on the lateral side of the front case 41, which is arranged to hold the end of the supporting rod 6 in a similar manner to the recessed portion 8 described above, so that the end of the supporting rod 6 is fixed to a given position on the lateral side of the front case 41. Providing the recessed portion also to the front case 41 allows the supporting rod 6 to support the front case 41 in a more stable manner.

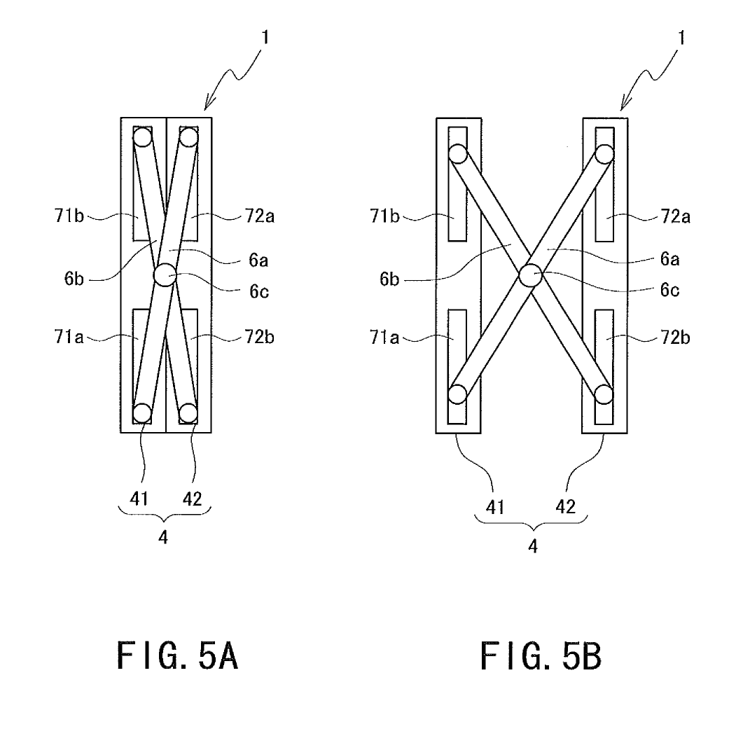

The display device according to the preferred embodiment of the present invention shown in FIG. 1 includes only one supporting rod while the display device according to another preferred embodiment of the present invention includes a plurality of supporting rods. Including the plurality of supporting rods can further improve support strength. FIGS. 5A and 5B are end views of the display device according to the present preferred embodiment of the present invention, and shown is the lateral side of the display device where the opening is provided, where the plurality of supporting rods are provided. The opening is closed in FIG. 5A, and the opening is opened in FIG. 5B. In the display device 1 shown in FIGS. 5A and 5B, two supporting rods 6a and 6b cross each other at connecting portions 6c that are substantial midpoints in longitudinal directions of the supporting rods 6a and 6b. On the lateral side of the cabinet 4, two guide slits 71a and 71b in line in the vertical direction are provided to the front case 41, and two guide slits 72a and 72b in line in the vertical direction are provided to the back case 42. One end of the supporting rod 6a is attached to the lower guide slit 71a of the front case 41 and the other end is attached to the upper guide slit 72a of the back case 42 so as to be vertically movable along the guide slits 71a and 72a. Meanwhile, one end of the supporting rod 6b is attached to the lower guide slit 72b of the back case 42 and the other end is attached to the upper guide slit 71b of the front case 41 so as to be vertically movable along the guide slits 71b and 72b.

As shown in FIG. 5A, while the front case 41 is closed and the opening 7 is accordingly closed, the supporting rods 6a and 6b are held by the cabinet 4 in a manner fixed to the lateral side of the cabinet 4 so as not to protrude forward or backward of the display device 1. When opening the front case 41, the supporting rods 6a and 6b move with their ends moving vertically along the guide slits 71 and 72. Supporting the front case 41 by the supporting rods 6a and 6b when opening the opening 7 allows the front case 41 to be held more securely. The two supporting rods 6a and 6b moves in conjunction with the opening and closing operation of the opening 7, which eliminates the need for extra operations of moving the supporting rods 6a and 6b in opening and closing the front case 41.

The positions on the opening sides of the front case 41 and the back case 42 where the supporting rod 6 connects the front case 41 and the back case 42 when the opening 7 is opened are not limited to the center positions shown in FIGS. 3A and 3B and FIGS. 5A and 5B, and they may be upper positions, lower positions, or intermediate positions between them (not shown).

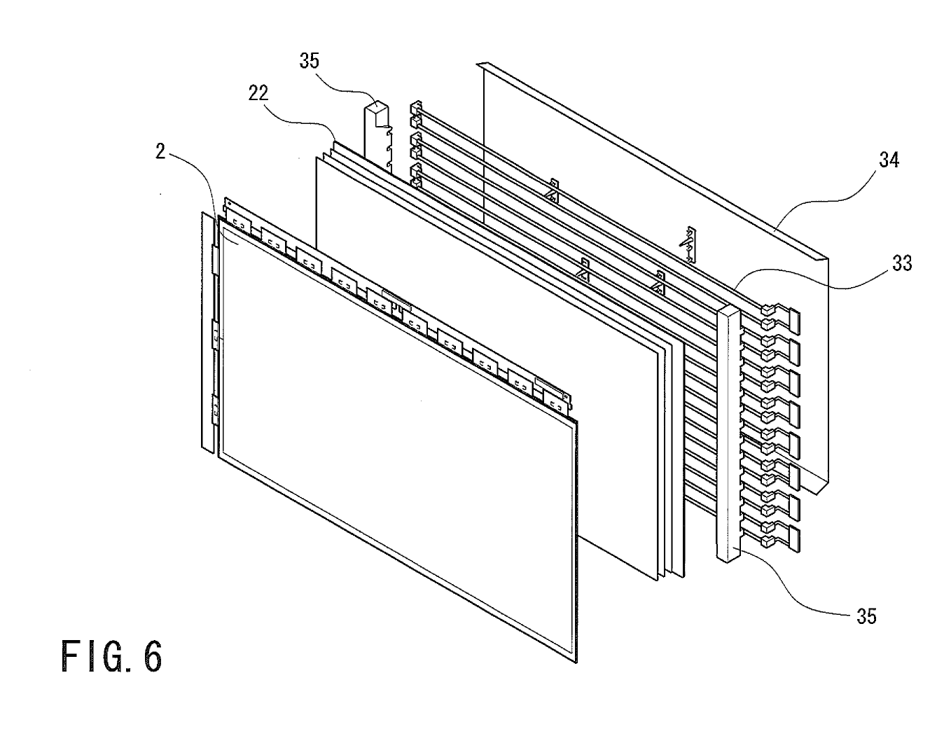

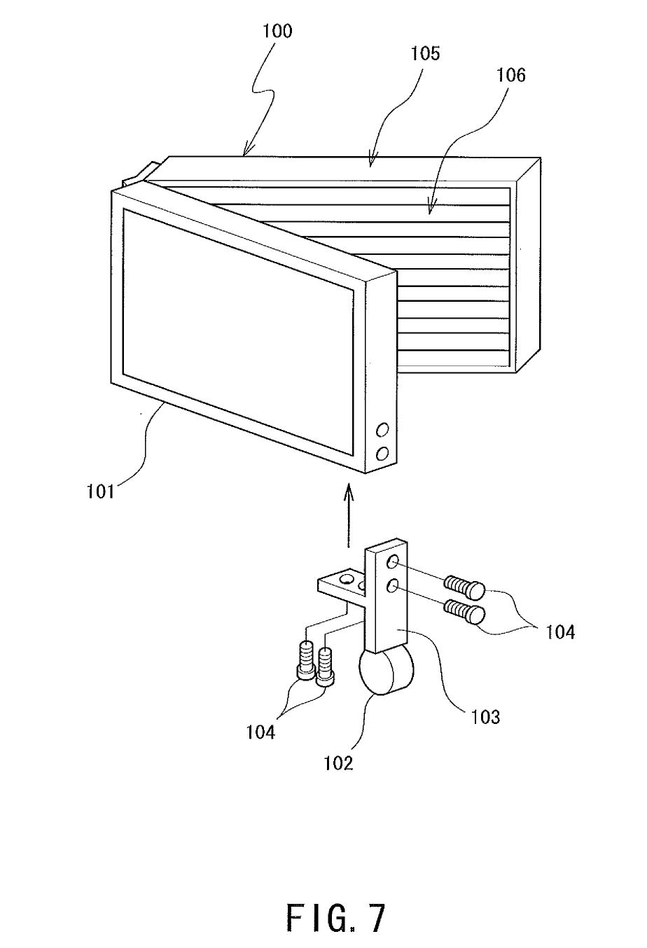

FIG. 6 is an exploded perspective view showing one example of the internal structure of the liquid crystal display device. As shown in FIG. 1, the liquid crystal display device 1 includes the cold cathode fluorescent tubes 33 that define the light source of the backlight unit 3, a reflection sheet 34 arranged to reflect light emitted from the fluorescent tubes 33, lamp holders 35 arranged to hold the fluorescent tubes 33 at right and left edge portions of the display device 1, optical sheets 22 arranged to control the properties of the light emitted from the fluorescent tubes 33, the liquid crystal panel 2 arranged to transmit the light that passes through the optical sheets 22 and display an image in a visible manner, and other components. Among those components, the fluorescent tubes 33, the reflection sheet 34, the lamp holders 35 and other components are accommodated in the back case 42, and the liquid crystal panel 2, the optical sheets 22 and other components are accommodated in the front case 41. The back case 42 accommodates also alight source driving circuit board and a light source driving circuit board cover (not shown).

A various types of conventional transmissive or transflective type liquid crystal panels may be used for the liquid crystal panel 2, and examples thereof include a commonly-used active matrix type liquid crystal panel. The liquid crystal display device 1 may be used for a television receiver. If used for a television receiver, the cabinet accommodates a tuner, a loudspeaker mechanism, an electric power supply and other components placed at given positions. These components are usually accommodated in the fixed case. For example, in the display device shown in FIG. 1, these components are accommodated in the back case.

In the preferred embodiments of the present invention, the display device 1 has the configuration that the front case 41 (the first case) opens; however, the present invention is not limited thereto, and the display device 1 may have a configuration that the back case 42 (the second case) opens while the front case is fixed. In addition, in the preferred embodiments of the present invention, the display device 1 has the configuration that the opening 7 is provided on the right side of the display device 1; however, the present invention is not limited thereto, and the display device 1 may have a configuration that the opening 7 is provided on the left side, the topside or the underside of the display device 1. In addition, in the preferred embodiments of the present invention, the cabinet 4 has a horizontally long shape; however, the present invention is not limited thereto, and the cabinet 4 may have a vertically long shape.

The display device according to the preferred embodiments of the present invention is not limited to a liquid crystal display device, and can be used for various types of display devices.

What is claimed is:

1. A display device comprising:
a cabinet comprising:
a first case that accommodates components;
a second case that accommodates components;
a hinge that is attached on sides of the first case and the second case and is arranged to connect the first case and the second case;
an opening that is openable and closable on a side of the cabinet, the side being opposite to the sides of the first and second cases of the cabinet on which the hinge is attached; and
a supporting unit that is attached on the side of the cabinet where the opening is provided, and is arranged to, when one of the first and second cases is opened, support the opened case.

2. The display device according to claim 1, wherein the supporting unit is arranged to move in conjunction with the opening and closing operation of the opening.

3. The display device according to claim 1, wherein the supporting unit is held by the cabinet in a manner fixed to the cabinet while the opening is closed.

4. The display device according to claim 1, further comprising a fixing unit arranged to fix the supporting unit in order to fix the opening in a predetermined open state.

5. The display device according to claim 1, wherein the supporting unit comprises a plurality of supporting units.

6. The display device according to claim 1, wherein the cabinet is arranged to turn to open in a horizontal direction, and the side of the cabinet on which the supporting unit is attached comprises a lateral side of the cabinet.

7. The display device according to claim 1, wherein the components accommodated in one of the first and second cases comprise a liquid crystal panel, and the components accommodated in the other case comprise a backlight unit.
